(19) United States
(12) Patent Application Publication
(10) Pub. No.: US 2026/0095128 A1
(43) Pub. Date: Apr. 2, 2026

(54) DUAL SWITCHING TECHNOLOGY POWER DRIVE TOPOLOGY

(71) Applicant: Raytheon Company, Tewksbury, MA (US)

(72) Inventors: Timothy J. Burgess, Tucson, AZ (US); Peter Richard Olejnik, Tucson, AZ (US)

(21) Appl. No.: 18/904,736

(22) Filed: Oct. 2, 2024

(51) Int. Cl. H03F 1/30; H03F 3/213

(52) U.S. Cl. CPC H03F 1/303; H03F 3/213; H03F 2200/33

(57) ABSTRACT

A system is provided including a driver architecture including: a first set of devices of a first transistor type; and a second set of devices of a second transistor type different from the first transistor type. The system includes control logic configured to provide control signals to the first set of devices and the second set of devices in association with selectively controlling the first set of devices and the second set of devices. The first set of devices and the second set of devices are configured to selectively drive a load based on the control signals.

### BACKGROUND

The present disclosure relates to power amplifiers and, in particular, to a power amplifier leveraging devices of different technology types.

Some power amplifiers for driving a load may employ a single type of device technology with fixed output rise times and fall times and saturation dissipation. Techniques for effectively driving a load by a power amplifier are desired.

### BRIEF DESCRIPTION

Example embodiments of the present disclosure are directed to a system including: a driver architecture including: a first set of devices of a first transistor type; and a second set of devices of a second transistor type different from the first transistor type; and control logic configured to provide control signals to the first set of devices and the second set of devices in association with selectively controlling the first set of devices and the second set of devices, where the first set of devices and the second set of devices are configured to selectively drive a load based on the control signals.

In any one or combination of the embodiments disclosed herein, the control logic is configured to selectively control: activation of a device of the first transistor type and deactivation of a corresponding device of the second transistor type; and deactivation of the device of the first transistor type and activation of the corresponding device of the second transistor type.

In any one or combination of the embodiments disclosed herein, the control logic is configured to control phase or duty cycle of power provided by the driver architecture.

In any one or combination of the embodiments disclosed herein, the control logic is configured to control on and off timing of the first set of devices and the second set of devices.

In any one or combination of the embodiments disclosed herein, the control logic is configured to selectively control the first set of devices and the second set of devices based on a target shaping of voltage or current to be provided by the driver architecture.

In any one or combination of the embodiments disclosed herein, the system further includes: processing circuitry configured to provide a shaping command associated with a target shaping of voltage or current to be provided by the driver architecture.

In any one or combination of the embodiments disclosed herein, the processing circuitry is configured to generate the shaping command based on a model associated with the load.

In any one or combination of the embodiments disclosed herein, the driver architecture includes an H-bridge architecture including the first set of devices of the first transistor type and the second set of devices of the second transistor type.

In any one or combination of the embodiments disclosed herein: the first transistor type includes a metal-oxide-semiconductor field-effect transistor; and the second transistor type includes a bipolar transistor.

In any one or combination of the embodiments disclosed herein, the first transistor type includes a metal-oxide-semiconductor field-effect transistor having first performance characteristics; and the second transistor type includes a metal-oxide-semiconductor field-effect transistor having second performance characteristics different from the first performance characteristics.

In any one or combination of the embodiments disclosed herein, the first transistor type includes a silicon carbide (SiC) metal-oxide-semiconductor field-effect transistor.

In any one or combination of the embodiments disclosed herein, the first transistor type includes a bipolar transistor having first performance characteristics; and the second transistor type includes a bipolar transistor having second performance characteristics different from the first performance characteristics.

In any one or combination of the embodiments disclosed herein, the first transistor type includes an insulated-gate bipolar transistor.

In any one or combination of the embodiments disclosed herein, the control logic is included in an application specific integrated circuit (ASIC).

In any one or combination of the embodiments disclosed herein, the control logic is included in a programmable device.

Example embodiments of the present disclosure are directed to an H-bridge driver architecture including: a first set of devices of a first transistor type; and a second set of devices of a second transistor type different from the first transistor type; where the first set of devices and the second set of devices are configured to selectively drive a load based on a control signal, where the control signal selectively controls activation or deactivation of the first set of devices and the second set of devices in association with driving the load.

In any one or combination of the embodiments disclosed herein: the first transistor type includes a metal-oxide-semiconductor field-effect transistor; and the second transistor type includes a bipolar transistor.

In any one or combination of the embodiments disclosed herein, the first transistor type includes a metal-oxide-semiconductor field-effect transistor having first performance characteristics; and the second transistor type includes a metal-oxide-semiconductor field-effect transistor having second performance characteristics different from the first performance characteristics.

In any one or combination of the embodiments disclosed herein, the first transistor type includes a bipolar transistor having first performance characteristics; and the second transistor type includes a bipolar transistor having second performance characteristics different from the first performance characteristics.

Example embodiments of the present disclosure are directed to a method including: generating control signals associated with driving a load; and providing the control signals to an H-bridge driver architecture including a first set of devices of a first transistor type and a second set of devices of a second transistor type different from the first transistor type, in association with driving the load, where providing the control signals selectively turns on or off devices included among the first set of devices and the second set of devices.

In any one or combination of the embodiments disclosed herein, providing the control signals is based on a target mode of operation associated with the H-bridge driver architecture.

Additional features and advantages are realized through the techniques of the present disclosure. Other embodiments and aspects of the disclosure are described in detail herein and are considered a part of the claimed technical concept. For a better understanding of the disclosure with the advantages and the features, refer to the description and to the drawings. Embodiments of the present disclosure are not limited to the examples provided herein.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1A illustrates an example of a system that supports a dual switching technology power drive topology in accordance with one or more embodiments of the present disclosure.

FIGS. 1B through 1D illustrate example aspects of a driver architecture of FIG. 1A implemented in association with the dual switching technology power drive topology.

FIG. 2 illustrates an example flowchart of a method in accordance with one or more embodiments of the present disclosure.

### DETAILED DESCRIPTION

A detailed description of one or more embodiments of the disclosed apparatus and method are presented herein by way of exemplification and not limitation with reference to the Figures.

Embodiments of the present disclosure provide a power amplifier configuration topology which includes multiple types of transistor technologies configured to operate in tandem in an H-Bridge control configuration. The systems and techniques described herein include using an algorithm to control rise time and fall time with low saturation mode power dissipation by controlling the duty cycle and phasing of the gate drives of the different types of transistor technologies (switching device technologies). The dual switching technology power drive topology may include, in control logic (e.g., an FPGA, an ASIC device), an algorithm which when executed is configured to control rise times and/or fall times. In some aspects, control of the rise times and/or fall times may optimize efficiency for the different transistor technologies over variations in temperature, voltage, load, and demand.

The systems and techniques described herein leverage the characteristics from the different switching technologies in driving a load. For example, the systems and techniques described herein may leverage the characteristics from the different switching device technologies in driving a load where a relatively slow switching dV/dt is desired and control the devices of different device technologies with an algorithm resident in the control logic (e.g., an FPGA, an ASIC device).

As will be described herein, the systems and techniques provide a power amplifier capable of effectively driving a load compared to some other amplifiers. For example, such other amplifiers may employ devices of a single device technology, and thus the devices may be limited to fixed output rise times, fall times, and saturation dissipation.

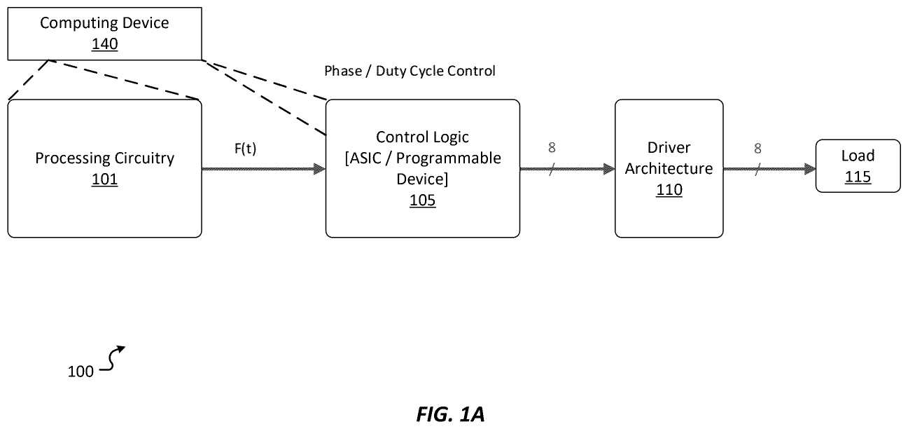

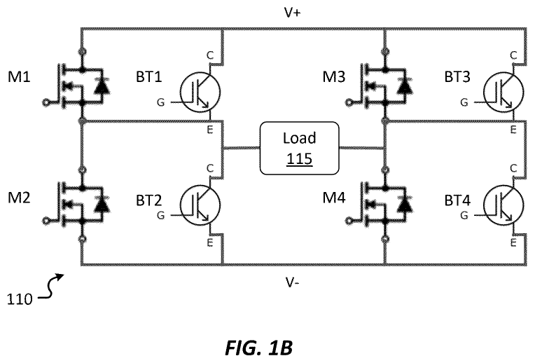

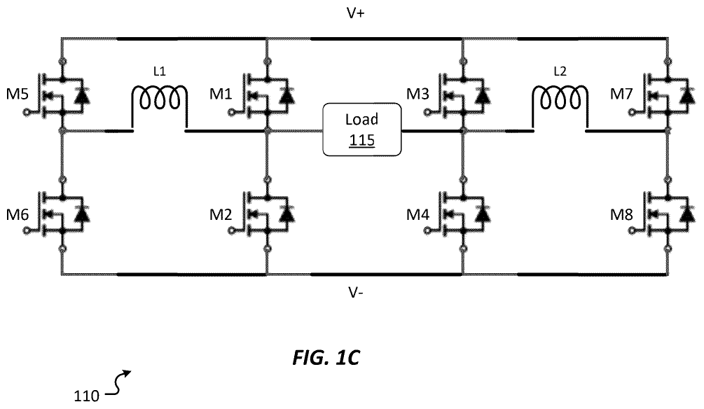

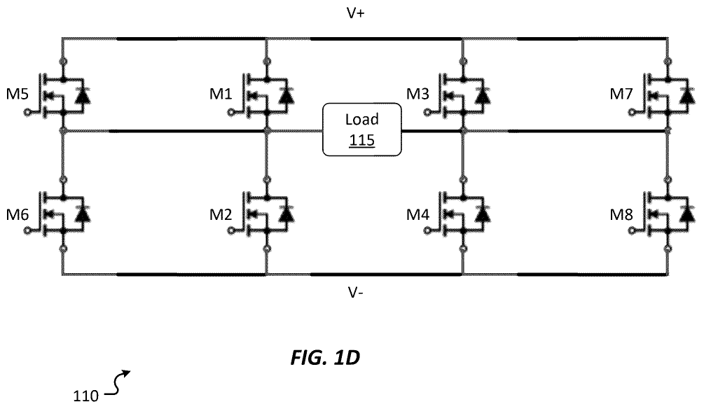

FIG. 1A illustrates an example of a system 100 that supports a dual switching technology power drive topology in accordance with one or more embodiments of the present disclosure. FIG. 1B illustrates example aspects of the driver architecture 110 of FIG. 1A implemented in association with the dual switching technology power drive topology. Aspects of the system may be implemented for motor control designs and high performing control actuation systems (e.g., electric motors), but are not limited thereto.

Example aspects of the system 100 and the driver architecture 110 in accordance with one or more embodiments of the present disclosure are described with reference to FIGS. 1A through 1D.

The system 100 may include processing circuitry 101, control logic 105, driver architecture 110, and a load 115. The processing circuitry 101, the control logic 105, or the driver architecture 110 may be included, for example, as a drive stage of a power amplifier. In some embodiments, the system 100 may include a computing device 140, example aspects of which are later described herein.

Although a single implementation of the driver architecture 110 is illustrated at FIG. 1A, embodiments of the present disclosure are not limited thereto. For example, the system 100 may include three instances of the driver architecture 110 (e.g., for providing 3-phase power).

With reference to FIGS. 1A and 1B, the driver architecture 110 may include devices M1 through M4 of a first transistor type (e.g., a first semiconductor technology, a first device type) and devices BT1 through BT4 of a second transistor type (e.g., a second semiconductor technology, a second device type) different from the first transistor type. Non-limiting examples of the first transistor type and the second transistor type are later described herein.

The processing circuitry 101 may provide commands to the control logic 105 in association with selectively activating or deactivating the devices M1 through M4 and the devices BT1 through BT4 included in the driver architecture 110. In an example, the commands may include or be based on target timings (e.g., active and inactive states) for the devices M1 through M4 and the devices BT1 through BT4.

The control logic 105 may provide control signals to the devices M1 through M4 and the devices BT1 through BT4 in association with selectively controlling the devices M1 through M4 and the devices BT1 through BT4. The devices M1 through M4 and the devices BT1 through BT4 may selectively drive a load 115 based on the control signals.

In some aspects, the control logic 105 may selectively control activation of a device (e.g., M1) of the first transistor type and deactivation of a corresponding device (e.g., BT1) of the second transistor type. In some aspects, the control logic 105 may selectively control deactivation of the device (e.g., M1) of the first transistor type and activation of the corresponding device (e.g., BT1) of the second transistor type. In some other aspects, the control logic 105 may selectively control simultaneous activation of a device (e.g., M1) of the first transistor type and activation of a corresponding device (e.g., BT1) of the second transistor type. However, embodiments of the present disclosure are not limited thereto, and the control logic 105 may selectively control activation and deactivation of all devices included in the driver architecture 110 in association with a target mode of operation suitable for driving the load 115 (e.g., for any suitable control possibilities associated with sequentially controlling activation and deactivation of the devices).

In some embodiments, the driver architecture 110 includes an H-bridge architecture including the devices M1 through M4 of the first transistor type and the devices BT1 through BT4 of the second transistor type.

In an example, the devices M1 through M4 may be metal-oxide-semiconductor field-effect transistors (MOSFETs), and the devices BT1 through BT4 may be bipolar transistors. In another example, the devices M1 through M4 may be silicon carbide (SiC) MOSFETs, and the devices BT1 through BT4 may be insulated-gate bipolar transistors (IGBTs). However, embodiments of the present disclosure are not limited thereto.

For example, in some other embodiments, the driver architecture 110 may be implemented with two different device types of the same technology (e.g., bipolar transistors of a first type and bipolar transistors of a second type, or MOSFETs of a first type and MOSFETs of a second type), which may leverage advantageous features associated with each device type.

That is, for example, the devices BT1 through BT4 may be bipolar transistors of the first type (e.g., having associated physical and/or performance characteristics), and in place of the devices M1 through M4, the driver architecture 110 may include devices BT5 through BT8 (not illustrated) of the second type (e.g., having associated physical and/or performance characteristics). For example, the devices BT1 through BT4 may be high current rated bipolar transistors, and the devices BT5 through BT8 (not illustrated) may be low current rated bipolar transistors, and the implementation of bipolar transistor types in the driver architecture 110 may support effective handling of transient/steady state varying load conditions.

In accordance with one or more embodiments of the present disclosure, using the control signals, the control logic 105 may control various characteristics of power to be provided by the driver architecture 110. For example, using the control signals, the control logic 105 may control phase or duty cycle of power to be provided by the driver architecture 110. In another example, using the control signals, the control logic 105 may control on and off timing of the devices M1 through M4 and the devices BT1 through BT4.

In some aspects, using the control signals, the control logic 105 may selectively control the devices M1 through M4 and the devices BT1 through BT4 based on a target shaping of voltage or current to be provided by the driver architecture 110. For example, based on the control signals, the driver architecture 110 may provide a voltage or current which satisfies the target shaping.

In some aspects, the processing circuitry 101 may provide a shaping command associated with the target shaping of voltage or current to be provided by the driver architecture 110. For example, the processing circuitry 101 may generate the shaping command based on a model associated with the load 115. For example, the load 115 may be an inductive load. For example, the load 115 may be a high performance reactive load (e.g., a motor, a 3-phase motor, a brushless 3-phase motor, or the like), and the computing device 140 may store a model corresponding to the high performance reactive load.

Accordingly, for example, by controlling the driver architecture 110 and driving the load 115 based on a model of the load 115, the system 100 is capable of providing model-assisted and sensorless implementations for controlling the driver architecture 110 and effectively driving the load 115.

Example aspects of selectively controlling the devices M1 through M4 and the devices BT1 through BT4 by a device (e.g., computing device 140, processing circuitry 101, control logic 105) in accordance with one or more embodiments of the present disclosure are described herein. In an example, selectively controlling the devices M1 through M4 and the devices BT1 through BT4 may be based one or more modes of operation and, in some aspects, control cycles associated with each mode of operation. Non-limiting examples of the modes and control cycles are described herein.

In a first control mode (Mode 1) described with reference to FIG. 1B, the processing circuitry 101 and control logic 105 may switch ON BT1 and BT4 (or BT2 and BT3 for reverse current flow through the load 115) in association with initiating a dI/dt limited current flow through the load 115. After a first duration (e.g., Δt1) has elapsed, after the transient current draw has satisfied a threshold criteria (e.g., after the transient current draw has settled), the processing circuitry 101 and control logic 105 may switch ON M1 and M4 (or M2 and M3 for reverse current flow through the load 115) to allow current to flow through the lower impedance devices (e.g., M1 and M4) in association with dissipating less power by the driver architecture 110. After a second duration (e.g., Δt1, or Δt2) has elapsed, the processing circuitry 101 and control logic 105 may switch OFF BT1 and BT4 (or BT2 and BT3 for reverse current flow through the load 115). After a third duration (e.g., Δt1, Δt2, or Δt3), the processing circuitry 101 and control logic 105 may switch OFF M1 and M4 (or M2 and M3 for reverse current flow through the load 115). The processing circuitry 101 and control logic 105 may repeat the cycle, beginning at switching ON BT1 and BT4 (or BT2 and BT3 for reverse current flow through the load 115).

In accordance with one or more embodiments of the present disclosure, the durations Δt1, Δt2, and Δt3 described with reference to the first control mode may be equal to or different from one another based on implementation.

With reference to FIGS. 1A and 1C, the driver architecture 110 may include devices M1 through M4 of a first transistor type and devices M5 through M8 of a second transistor type.

In a second control mode (Mode 2) described with reference to FIG. 1C, the processing circuitry 101 and control logic 105 may switch ON M5 and M8 (or M6 and M7 for reverse current flow through the load 115) in association with initiating a dI/dt limited current flow through inductor L1, inductor L2, and the load 115. After a first duration (e.g., Δt1) has elapsed, after the transient current draw has satisfied a threshold criteria (e.g., after the transient current draw has settled), the processing circuitry 101 and control logic 105 may switch ON M1 and M4 (or M2 and M3 for reverse current flow through the load 115) to allow current to bypass the inductors L1 and L2 and flow through a low power dissipation device (e.g., M1 and M4). After a second duration (e.g., Δt1, or Δt2) has elapsed, the processing circuitry 101 and control logic 105 may switch OFF M1, M4, M5, and M8 (or M2, M3, M6, and M7 for reverse current flow through load 115). The processing circuitry 101 and control logic 105 may repeat the cycle, beginning at switching ON M5 and M8 (or M6 and M7 for reverse current flow through load 115).

In accordance with one or more embodiments of the present disclosure, the durations Δt1 and Δt2 described with reference to the second control mode may be equal to or different from one another based on implementation.

With reference to FIGS. 1A and 1D, the driver architecture 110 may include devices M1 through M8 of the same transistor type or of similar transistor characteristics (e.g., similar saturation impedance).

In a third control mode (Mode 3) described with reference to FIG. 1D, the processing circuitry 101 and control logic 105 may switch ON M1, M4, M5 and M8 (or M2, M3, M6, and M7 for reverse current flow through the load 115) in association with driving current flow through the load 115 using two devices (e.g., M1 and M5, M4 and M8) with similar saturation impedance to share load current. In some aspects, driving current flow through the load 115 using two devices with similar saturation impedance may support the use of lower current rating devices. After a first duration (e.g., Δt1) has elapsed and/or in response to satisfaction of some other criteria, the processing circuitry 101 and control logic 105 may switch OFF M1, M4, M5 and M8 (or M2, M3, M6, and M7 for reverse current flow through the load 115). The processing circuitry 101 and control logic 105 may repeat the cycle, beginning at switching ON M1, M4, M5 and M8 (or M2, M3, M6, and M7 for reverse current flow through the load 115).

Embodiments of driver architecture 110 are not limited to the examples described herein, and the driver architecture 110 may be implemented with any suitable combination of switching devices of multiple respective device types that support functions of the driver architecture 110. For example, embodiments of the present disclosure support selective activation of the devices (of multiple respective device types) of the driver architecture 110, which may maximize efficiency while driving the load 115. For example, the systems and techniques described herein support using relatively standard MOSFETs and bipolar transistors for reduced cost, but in exchange for reduced performance. In another example, the systems and techniques described herein support using SiC MOSFETs and IGBTs for improved performance, but in exchange for increased cost.

Embodiments of the driver architecture 110 are not limited to the examples described herein. For example, the driver architecture 110 may be implemented with devices of three or more device types, and the system 100 may support selectively activating or deactivating the devices of the three or more device types in accordance with driving the load 115 using the techniques described herein.

In some embodiments, the control logic 105 may be implemented in an application specific integrated circuit (ASIC). In some other embodiments, the control logic 105 may be implemented in a programmable device (e.g., a field programmable gate array (FPGA)).

In some embodiments, the processing circuitry 101 and/or the control logic 105 may be included in the computing device 140. In some other embodiments, the processing circuitry 101 and/or the control logic 105 may be separate from and coupled to the computing device 140.

The computing device 140 may be disposed in operable communication with components of the system 100. The system 100 supports communication between the computing device 140 and other components or devices of the system 100 via wired communication protocols, wireless communication protocols (e.g., electromagnetic (EM) signals, WiFi, Bluetooth™, ZigBee™, Ubiquiti™, 3G, 4G, LTE, and the like), and/or combinations including one or more of the foregoing.

The computing device 140 is configured to receive, store and/or transmit data generated from components and devices of the system 100. The computing device 140 includes processing components configured to analyze received data. The computing device 140 includes processing components configured to provide data and/or control signals to other components of the system 100. The computing device 140 includes any number of suitable components, such as processors, memory, communication devices and power sources. The computing device 140 may include processing circuitry capable of executing instructions stored on a memory of the computing device 140 in association with performing one or more functions described herein.

In various embodiments, the system 100 may include user interface components such as, for example, a display screen, speaker, microphone, wearable devices, keyboard, mouse, printer, touchpad, controllers, and haptic devices. The computing device 140 and system 100 may provide data to a user or receive inputs from the user via the user interface components.

As described herein, aspects of the system 100 provide a dual switching technology power drive topology which may leverage characteristics of devices included in the driver architecture 110 for effectively driving the load 115. For example, IGBTs may have a relatively slow turn on time, which is desired when switching inductive loads, but may dissipate relatively high power in saturation. SiC MOSFETs may have a relatively fast turn on time, which is not desired when driving inductive loads, but dissipate relatively low power in saturation. Accordingly, for example, through the selective activation and deactivation of the devices M1 through M4 of the first transistor type and the devices BT1 through BT4 of the second transistor type, the driver architecture 110 may effectively drive an inductive load. Some other approaches have provided cascade solutions which switch systems at multiple frequencies, but such approaches do not employ multiple semiconductor technologies as described herein.

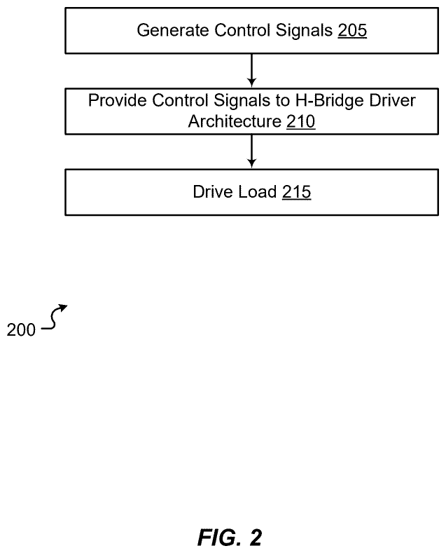

FIG. 2 illustrates an example flowchart of a method 200 in accordance with one or more embodiments of the present disclosure. The method 200 may be implemented by the example aspects of components (e.g., system 100, processing circuitry 101, control logic 105, driver architecture 110) described herein.

At 205, the method 200 includes generating control signals associated with driving a load.

At 210, the method 200 includes providing the control signals to an H-bridge driver architecture including a first set of devices of a first transistor type and a second set of devices of a second transistor type different from the first transistor type, in association with driving the load (at 215), where providing the control signals selectively turns on or off devices included among the first set of devices and the second set of devices.

In some aspects, providing the control signals may be based on a target mode of operation associated with the H-bridge driver architecture.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

The corresponding structures, materials, acts and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the technical concepts in the form disclosed. Many modifications and variations will be apparent to those of ordinary skill in the art without departing from the scope and spirit of the disclosure. The embodiments were chosen and described in order to best explain the principles of the disclosure and the practical application and to enable others of ordinary skill in the art to understand the disclosure for various embodiments with various modifications as are suited to the particular use contemplated.

While the various embodiments to the disclosure have been described, it will be understood that those skilled in the art, both now and in the future, may make various improvements and enhancements which fall within the scope of the claims which follow. These claims should be construed to maintain the proper protection for the disclosure first described.

What is claimed is:

1. A system comprising:
a driver architecture comprising:
a first set of devices of a first transistor type; and
a second set of devices of a second transistor type different from the first transistor type; and
control logic configured to provide control signals to the first set of devices and the second set of devices in association with selectively controlling the first set of devices and the second set of devices,
wherein the first set of devices and the second set of devices are configured to selectively drive a load based on the control signals.

2. The system of claim 1, wherein the control logic is configured to selectively control:
activation of a device of the first transistor type and deactivation of a corresponding device of the second transistor type; and
deactivation of the device of the first transistor type and activation of the corresponding device of the second transistor type.

3. The system of claim 1, wherein the control logic is configured to control phase or duty cycle of power provided by the driver architecture.

4. The system of claim 1, wherein the control logic is configured to control on and off timing of the first set of devices and the second set of devices.

5. The system of claim 1, wherein the control logic is configured to selectively control the first set of devices and the second set of devices based on a target shaping of voltage or current to be provided by the driver architecture.

6. The system of claim 1, further comprising processing circuitry configured to provide a shaping command associated with a target shaping of voltage or current to be provided by the driver architecture.

7. The system of claim 6, wherein the processing circuitry is configured to generate the shaping command based on a model associated with the load.

8. The system of claim 1, wherein the driver architecture comprises an H-bridge architecture comprising the first set of devices of the first transistor type and the second set of devices of the second transistor type.

9. The system of claim 1, wherein:
the first transistor type comprises a metal-oxide-semiconductor field-effect transistor; and
the second transistor type comprises a bipolar transistor.

10. The system of claim 1, wherein:
the first transistor type comprises a metal-oxide-semiconductor field-effect transistor having first performance characteristics; and
the second transistor type comprises a metal-oxide-semiconductor field-effect transistor having second performance characteristics different from the first performance characteristics.

11. The system of claim 10, wherein the first transistor type comprises a silicon carbide (SiC) metal-oxide-semiconductor field-effect transistor.

12. The system of claim 1, wherein:
the first transistor type comprises a bipolar transistor having first performance characteristics; and
the second transistor type comprises a bipolar transistor having second performance characteristics different from the first performance characteristics.

13. The system of claim 12, wherein the first transistor type comprises an insulated-gate bipolar transistor.

14. The system of claim 1, the control logic is comprised in an application specific integrated circuit (ASIC).

15. The system of claim 1, the control logic is comprised in a programmable device.

16. An H-bridge driver architecture comprising:
a first set of devices of a first transistor type; and
a second set of devices of a second transistor type different from the first transistor type;
wherein the first set of devices and the second set of devices are configured to selectively drive a load based on a control signal, wherein the control signal selectively controls activation or deactivation of the first set of devices and the second set of devices in association with driving the load.

17. The H-bridge driver architecture of claim 16, wherein:
the first transistor type comprises a metal-oxide-semiconductor field-effect transistor; and
the second transistor type comprises a bipolar transistor.

18. The H-bridge driver architecture of claim 16, wherein:
the first transistor type comprises a metal-oxide-semiconductor field-effect transistor having first performance characteristics; and
the second transistor type comprises a metal-oxide-semiconductor field-effect transistor having second performance characteristics different from the first performance characteristics.

19. The H-bridge driver architecture of claim 16, wherein:
the first transistor type comprises a bipolar transistor having first performance characteristics; and
the second transistor type comprises a bipolar transistor having second performance characteristics different from the first performance characteristics.

20. A method comprising:
generating control signals associated with driving a load; and
providing the control signals to an H-bridge driver architecture comprising a first set of devices of a first transistor type and a second set of devices of a second transistor type different from the first transistor type, in association with driving the load,
wherein providing the control signals selectively turns on or off devices comprised among the first set of devices and the second set of devices.
